(19) United States
(12) Patent Application Publication
(10) Pub. No.: US 2007/0172971 A1
(43) Pub. Date: Jul. 26, 2007

(54) Desiccant sealing arrangement for OLED devices

(75) Inventor: Michael L. Boroson, Rochester, NY (US)

Correspondence Address: Pamela R. Crocker;Patent Legal Staff, Eastman Kodak Company, 343 State Street, Rochester, NY, 14650-2201, US

(73) Assignee: Eastman Kodak Company

(21) Appl. No.: 11/336,539

(22) Filed: Jan. 20, 2006

(51) Int. Cl. H01L 21/00

(52) U.S. Cl. 438/26

(57) ABSTRACT

A method of encapsulating an OLED device, comprising: providing a substrate; forming an OLED device over the substrate, and a cover over the OLED device; and providing a desiccant sealing arrangement between the cover and the substrate, with the desiccant sealing arrangement provided by forming a perimeter seal and a spaced interior seal; a first desiccant material placed between the perimeter seal and the spaced interior seal; and a second desiccant material placed interior of the spaced interior seal.

### FIELD OF THE INVENTION

The present invention relates to protecting OLED devices from moisture.

### BACKGROUND OF THE INVENTION

An organic light-emitting diode device, also called an OLED device, commonly includes a substrate, an anode, a hole-transporting layer made of an organic compound, an organic luminescent layer with suitable dopants, an organic electron-transporting layer, and a cathode. OLED devices are attractive because of their low driving voltage, high luminance, wide-angle viewing, and capability for full-color flat emission displays. Tang et al. described this multilayer OLED device in their U.S. Pat. Nos. 4,769,292 and 4,885,211.

A common problem with OLED displays is sensitivity to water. Typical electronic devices require humidity levels in a range of about 2500 to below 5000 parts per million (ppm) to prevent premature degradation of device performance within a specified operating or storage life of the device. Control of the environment to this range of humidity levels within a packaged device is typically achieved by encapsulating the device or by sealing the device and a desiccant within a cover. Desiccants such as, for example, molecular sieve materials, silica gel materials, and materials commonly referred to as Drierite materials, are used to maintain the humidity level within the above range. Particular highly moisture-sensitive electronic devices, for example, organic light-emitting devices (OLED) or panels, require humidity control to levels below about 1000 ppm and some require humidity control below even 100 ppm. Such low levels are not achievable with desiccants of silica gel materials and of Drierite materials. Molecular sieve materials can achieve humidity levels below 1000 ppm within an enclosure if dried at a relatively high temperature. However, molecular sieve materials have a relatively low moisture capacity at humidity levels at or below 1000 ppm, and the minimum achievable humidity level of molecular sieve materials is a function of temperature within an enclosure: moisture absorbed, for example, at room temperature, can be released into the enclosure or package during temperature cycling to higher temperature, such, as, for example, to a temperature of 100° C. Solid water-absorbing particles used within such packaged devices include 0.2 to 200 μm particle size powders of metal oxides, alkaline earth metal oxides, sulfates, metal halides, or perchlorates, i.e. materials having relatively low values of equilibrium minimum humidity and high moisture capacity. However, such materials even when finely divided into powders of 0.2 to 200 μm particle size often chemically absorb moisture relatively slowly compared to the above-mentioned molecular sieve, silica gel, or Drierite materials. Such relatively slow reaction with water vapor leads to a measurable degree of performance degradation due to, for example, moisture absorbed on the inside of a device, moisture vapor present within the sealed device, and moisture permeating through the seal between the device and the cover following the sealing of the desiccant inside a device cover.

Some solid water-absorbing particles, particularly molecular sieve materials that entrain moisture by physical absorption within microscopic pores, require a dehydrating step at substantially elevated temperature prior to use within a device enclosure, thus increasing the number of process steps and calling for additional apparatus, such as, for example, a controllable furnace to achieve substantial dehydration.

Numerous publications describe methods and materials for controlling humidity levels within enclosed or encapsulated electronic devices. Kawami et al., in U.S. Pat. No. 5,882,761, has taught the use of a desiccant layer over the organic layers of an OLED display, between the substrate and the top seal. Kawami et al. teach the use of the following desiccants: alkali metal oxides, alkali earth metal oxides, sulfates, metal halides, and perchlorates. Such materials can be deposited in a predetermined shape by such techniques as vacuum vapor deposition, sputtering, or spin-coating. Boroson et al., in U.S. Pat. No. 6,226,890, disclose the use of a castable blend of the above desiccants with a suitable binder. However, many desiccating agents can be reactive toward the layers and electrodes of OLED devices, and a number of ways have been proposed to keep the desiccating agents from contacting the OLED components. Kawami et al., in the '761 patent, have taught that the drying agent is to be coated on the inside surface of an airtight container. Boroson et al., in the '890 patent, use the castable blend to coat the interior surface of an enclosure. Techniques such as these require additional materials and efforts.

Tsuruoka et al., in U.S. Patent Application Publication 2003/0110981, have disclosed a series of transparent drying agents which operate by chemisorption and can be used in an OLED display. These are conceived as useful in OLED devices wherein one wishes to allow light emission through a desiccant layer. However, a desiccant—especially a chemisorption desiccant—is designed to change in the presence of moisture. Therefore, it is possible that the properties of the optical path of the device will change during the device lifetime, leading to potential visual changes in the display. This can limit the usefulness of this method.

Selection of solid water-absorbing particles and the method of applying selected particles to an inner portion of a device enclosure prior to sealing the device within or by the enclosure is governed by the type of device to be protected from moisture. For example, highly moisture-sensitive organic light-emitting devices or polymer light-emitting devices require the selection of particular solid water-absorbing particles and methods of application, since organic materials or organic layers are integral constituents of such devices. The presence of organic materials or layers may, for example, preclude the use of certain solvents or fluids in the application of fluid-dispersed solid water-absorbing particles to organic-based devices. Furthermore, a thermal treatment, if required, of a desiccant contained within a sealed device enclosure, needs to be tailored to the constraints imposed by thermal properties of the organic constituents or layers of the device. At any rate, release of solvent vapors during a thermal treatment of a desiccant disposed within a sealed device enclosure must be avoided or minimized if solvent vapors can adversely affect organic constituents of the device.

Shores, in U.S. Pat. Nos. 5,304,419; 5,401,536, and 5,591,379 discloses moisture gettering compositions and their use for electronic devices. However, many of the desiccants disclosed by Shores will not function effectively with highly moisture-sensitive devices at a humidity level lower than 1000 ppm. Similarly, binders, such as polyethylene disclosed by Shores, which have low moisture absorption rates compared to the absorption rate of the pure selected desiccants, would not function effectively to achieve and to maintain a humidity level below 1000 ppm during a projected operational lifetime of a highly moisture-sensitive device.

Deffeyes, U.S. Pat. No. 4,036,360 describes a desiccating material that is useful as a package insert or on the interior walls of packaging boxes for applications requiring only moderate moisture protection, such as film or cameras. The material comprises a desiccant and a resin having a high moisture vapor transmission rate. The desiccants disclosed by Deffeyes are alumina, bauxite, calcium sulfate, clay, silica gel, and zeolite, but Deffeyes does not describe the particle size of any of the desiccants. None of these desiccants will function effectively with highly moisture-sensitive devices at a humidity level lower than 1000 ppm. In addition the moisture vapor transmission rate requirement for the resin is not adequately defined since there is no reference to the thickness of the measured resins. A material that transmits 40 grams per 24 hrs per 100 in² at a thickness of 1 mil would be very different than one that transmits 40 grams per 24 hrs per 100 in² at a thickness of 100 mils. It is therefore not possible to determine if the moisture vapor transmission rates disclosed by Deffeyes are sufficient for highly moisture-sensitive devices.

Booe, U.S. Pat. No. 4,081,397, describes a composition used for stabilizing the electrical and electronic properties of electrical and electronic devices. The composition comprises alkaline earth oxides in an elastomeric matrix. The desiccants disclosed by Booe are barium oxide, strontium oxide, and calcium oxide. Booe teaches the use of particle sizes less than 80 mesh (177 μm) to minimize the settling of oxides within the suspension. Booe does not teach the impact of particle size on desiccant performance. These desiccants will function effectively with highly moisture-sensitive devices at humidity levels lower than 1000 ppm; however, Booe claims the elastomeric matrix has the property of retarding the fluid absorption rate of the alkaline earth particles. In the examples, the water-absorption rate of the compositions is 5 to 10 times slower than the alkaline earth particles alone. This decrease in absorption rate is disclosed as a desirable feature that improves the handling of the highly reactive alkaline earth oxides. In highly moisture-sensitive devices, however, any decrease in the absorption rate of moisture will increase the likelihood of device degradation, and identification of resins that will increase the absorption rate of moisture would be highly desirable. For highly moisture-sensitive devices, therefore, it is important to determine the minimum allowable water vapor transmission rate of the binders used in combination with effective desiccant materials.

Organic light emitting diode (OLED) devices are moisture-sensitive electronic devices that can benefit from improved methods of providing desiccants and have a need for reduced moisture transmission rate into the device. Attempts at this in the art have been less than satisfactory. Kim et al. in U.S. Patent Application Publication 2003/0127976 A1 teach the use of two sealants surrounding an OLED device. While this can be a way to reduce the likelihood of sealant failure, it may be no more effective at reducing moisture transmission rate into the device than would be a single wider sealant. Wang et al. in U.S. Patent Application Publication 2003/0122476 A1 show the use of two seals surrounding an OLED device with a desiccant between the two seals. This can reduce the moisture transmission rate into the device. However, Wang et al. require the use of ribs that must be formed between the seals in order to hold the desiccant, adding complexity and expense to the fabrication process. Peng in U.S. Pat. No. 6,589,675 B2 also teaches the use of two seals with a desiccant between them. However, Peng requires the use of a separate sealing ring to hold the desiccant, adding extra steps and complexity to the fabrication process. In addition, neither Wang et al. nor Peng provide protection for the OLED devices from any moisture that penetrates the interior seal.

Therefore, there still remains the need to reduce moisture transmission rate into highly moisture-sensitive devices, such as OLED devices, in a way that does not add to the complexity of the fabrication process, and also the need to protect these highly moisture sensitive devices from any moisture that penetrates the protective seals encapsulating these devices.

### SUMMARY OF THE INVENTION

It is therefore an object of the present invention to reduce the permeability of moisture into an OLED device. It is a further object of this invention to provide the reduced moisture permeability without the need for complex structures as part of the substrate or cover. It is a further object of this invention to protect an OLED device from any moisture that penetrates the sealed region containing the OLED device.

These objects are achieved by a method of encapsulating an OLED device, comprising:

(a) providing a substrate;

(b) forming an OLED device over the substrate, and a cover over the OLED device; and

(c) providing a desiccant sealing arrangement between the cover and the substrate, with the desiccant sealing arrangement provided by forming:
(i) a perimeter seal and a spaced interior seal;
(ii) a first desiccant material placed between the perimeter seal and the spaced interior seal; and
(iii) a second desiccant material placed interior of the spaced interior seal.

It is an advantage of this invention that it reduces the level of moisture inside OLED devices and the permeability of moisture into such devices. It is a further advantage of this invention that it can do this while relying less on highly active desiccants, thus improving ease of manufacture and reducing cost. It is a further advantage of this invention that OLED displays can be formed without the need of completely hermetic seals. It is a further advantage of this invention that it protects OLED devices from moisture that penetrates the sealed region containing the OLED device.

### BRIEF DESCRIPTION OF THE DRAWINGS

FIG. 1a shows a cross-sectional view of one embodiment of an OLED device encapsulated by the method of this invention;

FIG. 1b shows a plan view of the above OLED device;

FIG. 2 shows a cross-sectional view of another embodiment of an OLED device encapsulated by the method of this invention;

FIG. 3 shows a cross-sectional view of another embodiment of an OLED device encapsulated by the method of this invention;

FIG. 4 shows a block diagram of one embodiment of the method of this invention;

FIG. 5 shows a block diagram of another embodiment of the method of this invention; and

FIG. 6 is a graph showing the impact of seal width on required desiccant width due to moisture permeability of an OLED device.

Since device feature dimensions such as layer thicknesses are frequently in sub-micrometer ranges, the drawings are scaled for ease of visualization rather than dimensional accuracy.

### DETAILED DESCRIPTION OF THE INVENTION

The term “OLED device” or “organic light-emitting display” is used in its art-recognized meaning of a display device having organic light-emitting diodes as pixels. A color OLED device emits light of at least one color. The term “multicolor” is employed to describe a display panel that is capable of emitting light of a different hue in different areas. In particular, it is employed to describe a display panel that is capable of displaying images of different colors. These areas are not necessarily contiguous. The term “full color” is commonly employed to describe multicolor display panels that are capable of emitting in the red, green, and blue regions of the visible spectrum and displaying images in any combination of hues. The red, green, and blue colors constitute the three primary colors from which all other colors can be generated by appropriate mixing. However, the use of additional colors to extend the color gamut of the device is possible. The term “bottom-emitting” refers to display devices that emit light and are viewed through the substrate upon which they are based. The term “top-emitting” refers to display devices in which light is primarily not emitted through the substrate but opposite to the substrate, and are viewed through the side opposite to the substrate.

The term “highly moisture-sensitive electronic device” is employed to designate any electronic device that is susceptible to a measurable degradation of device performance at ambient moisture levels greater than 1000 ppm. The term “substrate” is employed to designate organic, inorganic, or combination organic and inorganic solids on which one or more highly moisture-sensitive electronic devices are fabricated. The term “sealing material” is employed to designate organic, inorganic, or combination organic and inorganic materials used to bond encapsulation enclosures to substrates and to protect one or more highly moisture-sensitive electronic devices from moisture by preventing or limiting moisture permeation through the sealing materials. The term “desiccant” is employed to designate organic or inorganic materials used to physically or chemically absorb or react with moisture that would otherwise damage the highly moisture-sensitive electronic devices.

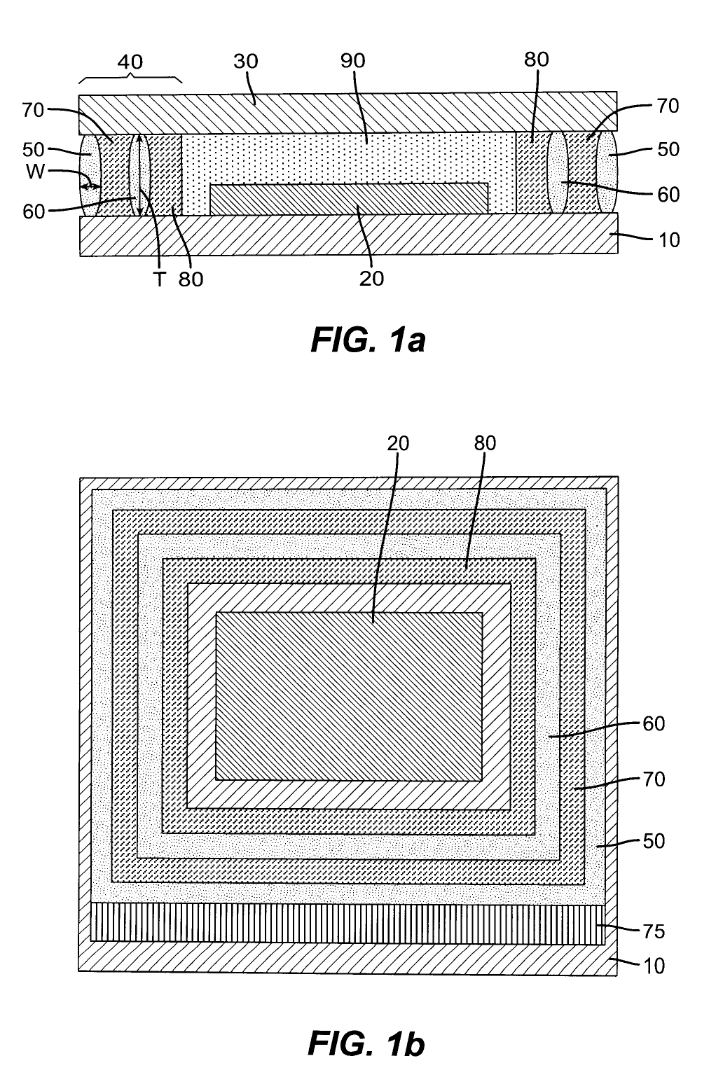

Turning now to FIG. 1a, there is shown a cross-sectional view of one embodiment of an OLED device encapsulated by the method of this invention. An OLED device 20 is formed over a substrate 10. A cover 30 is provided over OLED device 20. A desiccant sealing arrangement 40 is provided between cover 30 and substrate 10 and is provided by two seals and two desiccant materials: a perimeter seal 50, an interior seal 60 that is spaced from perimeter seal 50, a first desiccant material 70 placed between perimeter seal 50 and interior seal 60, and a second desiccant material 80 placed interior of interior seal 60. Although not shown, desiccant sealing arrangement 40 can include additional seals and desiccant materials.

Substrate 10 can be an organic solid, an inorganic solid, or a combination of organic and inorganic solids. Substrate 10 can be rigid or flexible and can be processed as separate individual pieces, such as sheets or wafers, or as a continuous roll. Typical substrate materials include glass, plastic, metal, ceramic, semiconductor, metal oxide, metal nitride, metal sulfide, semiconductor oxide, semiconductor nitride, semiconductor sulfide, carbon, or combinations thereof, or any other materials commonly used in the formation of OLED devices, which can be either passive-matrix devices or active-matrix devices. Substrate 10 can be a homogeneous mixture of materials, a composite of materials, or multiple layers of materials. Substrate 10 can be an OLED substrate, that is a substrate commonly used for preparing OLED devices, e.g. active-matrix low-temperature polysilicon or amorphous-silicon TFT substrate. For this application, where the EL emission is viewed through the top electrode, the transmissive characteristic of the bottom support is immaterial, and therefore can be light transmissive, light absorbing or light reflective.

Cover 30 can be an organic solid, an inorganic solid, or a combination of organic and inorganic solids. Cover 30 can be rigid or flexible, and can be processed as separate individual pieces, such as sheets or wafers, or as continuous rolls. Typical protective cover materials include glass, plastic, metal, ceramic, semiconductor, metal oxide, metal nitride, metal sulfide, semiconductor oxide, semiconductor nitride, semiconductor sulfide, carbon or combinations thereof. The portion of cover 30 over OLED device 20 is transparent if OLED device 20 is top-emitting, but portions that cover non-emitting regions can be opaque. Cover 30 can be a homogeneous mixture of materials, a composite of materials, multiple layers of materials, or an assembly of multiple materials such as a transparent window with an opaque frame.

Cover 30 can be spaced from OLED device 20, and an adhesive material 90 can be disposed between OLED device 20 and cover 30. Adhesive material 90 can be any number of materials, including UV or heat cured epoxy resin, acrylates, or pressure sensitive adhesive. The adhesive material 90 can also function as a protective layer. An example of a useful UV-curable epoxy resin is Optocast 3505 from Electronic Materials Inc. An example of useful pressure sensitive adhesive is Optically Clear Laminating Adhesive 8142 from 3M.

Perimeter seal 50 and interior seal 60 each comprise a sealing material, which can be organic, inorganic, or a combination of organic and inorganic. In an embodiment preferred for manufacturing simplicity, the same materials are used for perimeter seal 50 and interior seal 60; however, this invention is not limited to this configuration and the materials can be different for both seals. The organic sealing material can include epoxies, polyurethanes, acrylates, silicones, polyamides, polyolefins, and polyesters, or combinations thereof. The inorganic sealing material can include glass, ceramic, metal, semiconductor, metal oxide, semiconductor oxide, and metal solder, or combinations thereof. The sealing material can be bonded between substrate 10 and cover 30 in a bonding step accomplished by pressing, by melting and cooling, by reaction curing, or by a combination thereof. Typical materials bonded by pressure include pressure-sensitive adhesives. Typical materials bonded by melting and cooling include glass; hot melt adhesives such as polyolefins, polyesters, polyamides, or combinations thereof; or inorganic solders such as indium, tin, lead, silver, gold, or combinations thereof. Typical reaction curing methods include reactions resulting from heat, radiation such as UV radiation, mixing of two or more components, removal of ambient oxygen, or combinations thereof. Typical materials bonded by reaction curing include acrylates, epoxies, polyurethanes, silicones, or combinations thereof. Other inorganic materials typically used in sealing materials include glass, ceramic, metal, semiconductor, metal oxide, semiconductor oxide, or combinations thereof.

For the purposes of this discussion, the thickness of the seal is defined as the extent of the seal in the dimension labeled T and the width of the seal is defined as the extent of the seal in the dimension labeled W in FIG. 1a.

Second desiccant material 80 is used to physically or chemically absorb or react with moisture that would otherwise damage the highly moisture-sensitive OLED device 20. The level of moisture inside interior seal 60 must be kept below 1000 ppm, and in some cases even lower. Therefore, second desiccant material 80 has an equilibrium humidity level less than 1000 ppm. Typical moisture-absorbing materials meeting this requirement include metals such as alkali metals (e.g. Li, Na), alkaline earth metals (e.g. Ba, Ca), or other moisture-reactive metals (e.g. Al, Fe); alkaline metal oxides (e.g. Li₂O, Na₂O); alkaline earth metal oxides (e.g. MgO, CaO, BaO); sulfates (e.g. anhydrous MgSO₄); metal halides (e.g. CaCI₂); perchlorates (e.g. Mg(CIO₄)₂); molecular sieves; organometallic compounds described by Takahashi et al. in U.S. Pat. No. 6,656,609 and by Tsuruoka et al. in U.S. Patent Application Publication 2003/0110981, including organometallic compounds of the type: 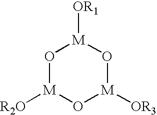
wherein R₁, R₂, and R₃ are selected from the group consisting of alkyl groups, aryl groups, cycloalkyl groups, heterocyclic groups, and acyl groups having one or more carbon atoms, and M is a trivalent metallic atom; organometallic compounds of the type: 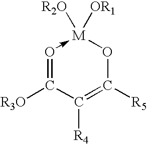
wherein each of R₁, R₂, R₃, R₄, and R₅ is selected from the group consisting of alkyl groups, alkenyl groups, aryl groups, cycloalkyl groups, heterocyclic groups, and acyl groups having one or more carbon atoms, and M is a trivalent metal atom; organometallic compounds of the type: 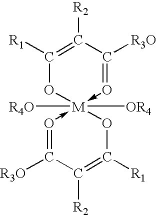
wherein each of R₁, R₂, R₃, and R₄ is selected from the group consisting of alkyl groups, alkenyl groups, aryl groups, cycloalkyl groups, heterocyclic groups, and acyl groups having one or more carbon atoms, and M is a tetravalent metal atom; and metals with work functions less than 4.5 eV and capable of being oxidized in the presence of moisture, or combinations thereof. Moisture-absorbing material can be packaged within moisture permeable containers or binders. Second desiccant material 80 can be a single material, a homogeneous mixture of materials, a composite of materials, or multiple layers of materials, and can be deposited from a vapor or from solution, or they can be provided in a porous matrix such as a permeable package or tape. Particularly useful desiccant materials include those that are particulate materials formed into a polymeric matrix that can be patterned, as described by Boroson et al. in U.S. Pat. No. 6,226,890.

First desiccant material 70 in this invention will serve primarily to remove a portion of the moisture that passes through perimeter seal 50. Thus, first desiccant will function to reduce the partial pressure of water vapor against interior seal 60, thus reducing the rate at which second desiccant material 80—and therefore OLED device 20—will degrade. Since the function of first desiccant material 70 is to reduce the partial pressure of water vapor, it can comprise a desiccant material with an equilibrium humidity level less than 1000 ppm, or a desiccant material with an equilibrium humidity level greater than 1000 ppm. Examples of the former include those described above for second desiccant material 80. Some examples of the latter include silica gel, materials commonly referred to as Drierite materials, and molecular sieves that have not been treated at high temperatures.

The desiccant materials can be expanding or non-expanding desiccants. By an expanding desiccant, we mean a desiccant that expands in volume upon absorbing moisture. Examples of expanding desiccants include reactive metals such as Li and oxides such as CaO. Such desiccants, when placed between perimeter seal 50 and interior seal 60, must not fill the entire gap between the seals. Non-expanding desiccants, such as molecular sieves, have an advantage in that they can fill the entire gap between the seals, thus increasing the likelihood that moisture passing through perimeter seal 50 will interact with and be absorbed by first desiccant 70.

It is a preferred embodiment of this invention that substrate 10 and cover 30 each define two coplanar surfaces, that is, they each have top and bottom surfaces that define parallel planes without additional surface features such as grooves or ledges. However, the invention is not limited to this configuration, and either substrate 10 or cover 30 or both can be non-coplanar, as will be seen.

Turning now to FIG. 1b, there is shown a plan view of the above OLED device 20. For clarity, cover 30 is not shown in this view. OLED device 20 is formed over substrate 10, and a contact pad 75 provides the electrical connections required to drive OLED device 20. Perimeter seal 50 provides a first seal around OLED device 20, and spaced interior seal 60 provides a second seal. First desiccant material 70 is placed between perimeter seal 50 and interior seal 60, and second desiccant material 80 is placed interior of interior seal 60. Together, seals 50 and 60 and desiccant materials 70 and 80 provide a desiccant sealing arrangement that completely encloses and seals OLED device 20 in the gap between substrate 10 and cover 30.

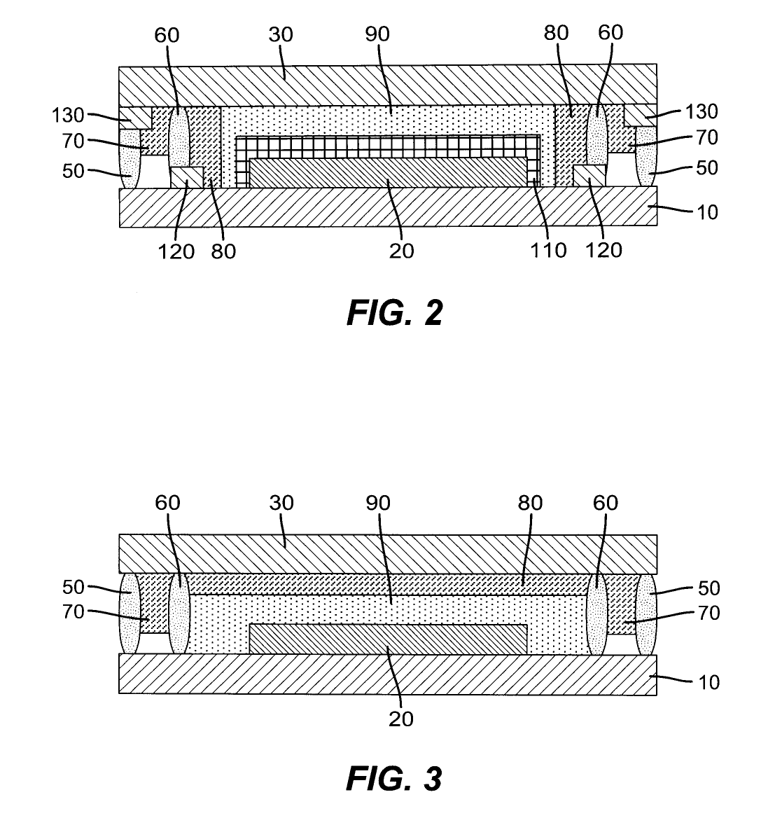

Turning now to FIG. 2, there is shown a cross-sectional view of another embodiment of an OLED device encapsulated by the method of this invention. As in FIG. 1, an OLED device 20 is formed over a substrate 10 and a cover 30 over OLED device 20. OLED device is sealed with perimeter seal 50 and spaced interior seal 60, and with first desiccant material 70 and second desiccant material 80. FIG. 2 also shows a thin-film encapsulation layer 110 provided over OLED device 20 to prevent contamination of the light-producing unit by oxygen or moisture. Thin-film encapsulation layer 110 can include organic, inorganic, or mixed organic and inorganic materials and can include a single layer or multiple layers of different materials or mixtures of materials. Some non-limiting examples of thin-film encapsulation layer materials include metal oxides such as aluminum oxide; metal nitrides; metal oxynitrides; diamond-like carbon; semiconductor oxides such as silicon dioxide; semiconductor nitrides such as silicon nitride; semiconductor oxynitrides such as silicon oxynitride; multilayer materials such as aluminum oxide/acrylate polymers as provided by Vitex Corp.; polymer layers such as parylene, epoxy, polyester, polyolefins, etc.; organic or organometallic compounds such as aluminum trisoxine (ALQ) or 4,4′-Bis[N-(1-naphthyl)-N-phenylamino]biphenyl (NPB); multiple layers of organic, inorganic, or both organic and inorganic materials; or mixtures of any of these. Thin-film encapsulation layer 110 is typically provided in a thickness of ten to several hundreds of nanometers.

Useful techniques of forming layers of thin-film encapsulation layer material from a vapor phase include, but are not limited to, thermal physical vapor deposition, sputter deposition, electron beam deposition, chemical vapor deposition, plasma-enhanced chemical vapor deposition, laser-induced chemical vapor deposition, atomic layer deposition, screen printing, and spin coating. In some instances, the materials can be deposited from a solution or another fluidized matrix, e.g., from a supercritical solution of C0₂. Care must be taken to choose a solvent or fluid matrix that does not negatively affect the performance of the OLED device. Patterning of the materials can be achieved by many ways including, but not limited to, photolithography, lift-off techniques, laser ablation, and shadow mask technology.

The seals of this embodiment also include glass ledges 120 and 130. The purpose of the glass ledges 120 and 130 is to reduce the thickness of perimeter seal 50, interior seal 60, or both. Reducing the thickness of the seals reduces the opportunity for moisture to pass into the interior of the encapsulated OLED device, as the seal is the most likely contamination point. The encapsulated OLED device can include a ledge for perimeter seal 50, or a ledge for interior seal 60, or both. Ledge 120 is shown as part of substrate 10 and ledge 130 is shown as part of cover 30. However, many other configurations are possible, e.g. both ledges can be on substrate 10 or cover 30, or a single ledge can be on either substrate 10 or cover 30.

In this embodiment, first desiccant material 70 is shown as only filling part of the cavity between perimeter seal 50 and interior seal 60. Such an arrangement is advantageous when the desiccant material expands upon absorbing moisture, e.g. calcium oxide. In such an arrangement, the distance provided between first desiccant material 70 and substrate 10 is less than the thickness of perimeter seal 50. Since small amounts of moisture will pass through perimeter seal 50, this arrangement improves moisture absorption by first desiccant material 70.

Turning now to FIG. 3, there is shown a cross-sectional view of another embodiment of an OLED device encapsulated by the method of this invention. In addition to features already discussed in regard to other embodiments, second desiccant material 80 is coated on the interior surface of cover 30. Such an arrangement is possible when OLED device 20 is a bottom-emitting device, that is, when it emits its light through substrate 10. Alternatively, OLED device 20 can be a top-emitting device if second desiccant material 80 is a transparent desiccant material, such as disclosed by Tsuruoka et al. in US Patent Application Publication 2003/0110981 and OleDry desiccants available from Futaba.

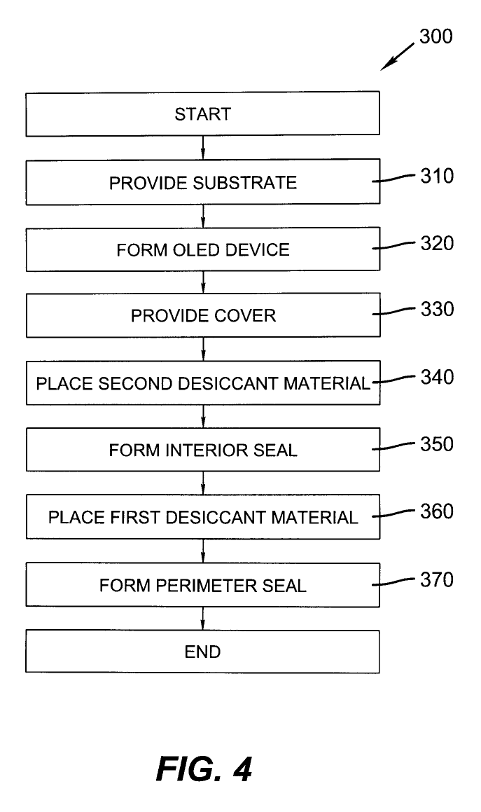

Turning now to FIG. 4, and referring also to FIG. 1a, there is shown a block diagram of one embodiment of the method of encapsulating an OLED device according to this invention. At the start of method 300, a substrate 10 is provided (Step 310). An OLED device 20 is formed on substrate 10 (Step 320) and a cover 30 is provided (Step 330). Then second desiccant material 80 is placed in the gap between substrate 10 and cover 30 (Step 340) and interior seal 60 is formed around second desiccant material 80 (Step 350). Then first desiccant material 70 is placed around interior seal 60 (Step 360) and perimeter seal 50 is formed around first desiccant material 70 (Step 370), completing the process.

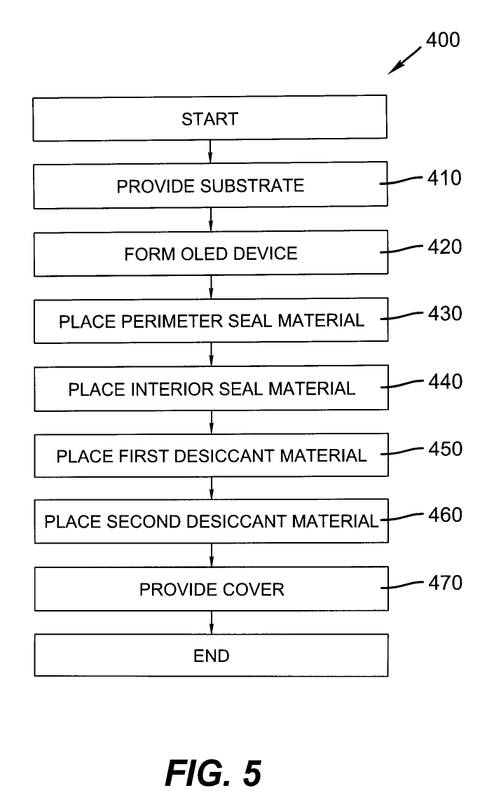

It will be understood that many variations of these steps are possible. For example, turning now to FIG. 5, and referring also to FIG. 1, there is shown a block diagram of another embodiment of the method of encapsulating an OLED device according to this invention. At the start of method 400, a substrate 10 is provided (Step 410). An OLED device 20 is formed on substrate 10 (Step 420). Then the material to form perimeter seal 50 is provided onto substrate 10 (Step 430) and the material to form interior seal 60 is also provided onto substrate 10 (Step 440). First desiccant material 70 is placed between the materials for interior seal 60 and perimeter seal 50 (Step 450), and second desiccant material 80 is placed interior to the material for interior seal 60 (Step 460). Then cover 30 is placed over substrate 10 with the desiccant and sealing materials (Step 470), forming the completed seals and completing the process. In other embodiments, one or both of the sealing materials and one or both of the desiccant materials can be placed on cover 30 instead of substrate 10.

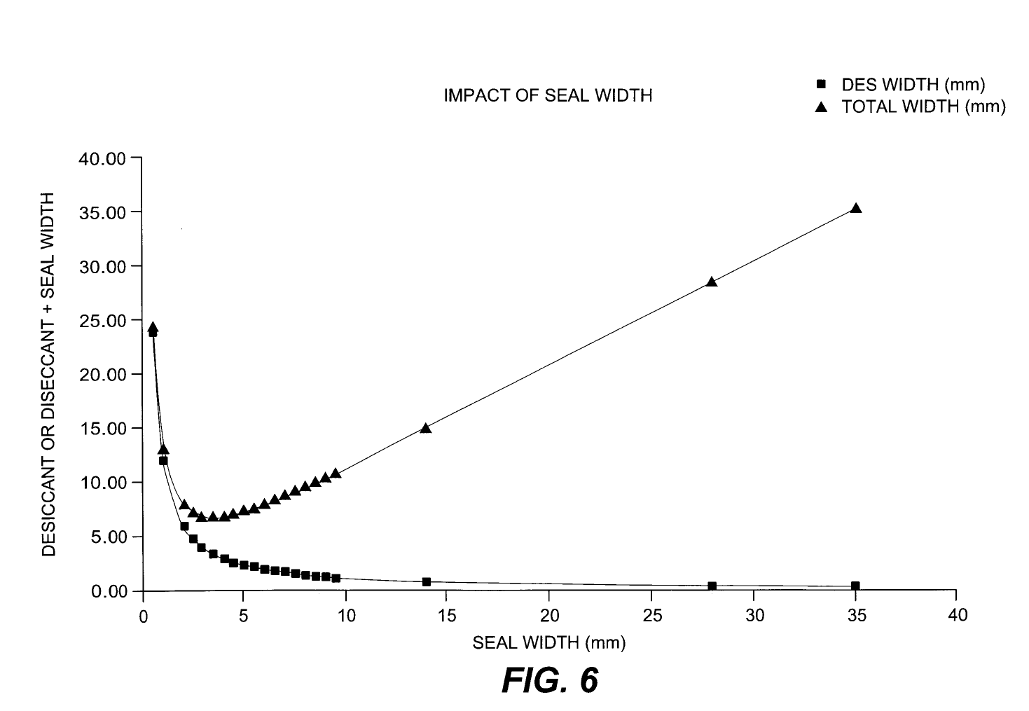

Turning now to FIG. 6, there is shown the relationship of the required width of first desiccant material 70 to the width of perimeter seal 50, and the relationship of the total width of first desiccant material 70 and perimeter seal 50 to the width of perimeter seal 50 for an OLED device 20 encapsulated by one embodiment of the method of this invention (that shown in FIG. 1a). As shown, the required width of first desiccant material 70 decreases as the width of perimeter seal 50 increases. This decrease in the required width of first desiccant material 70 is due to the decrease in: 1) the rate of moisture permeation, and 2) the total amount of moisture permeation over the lifetime of OLED device 20 as the width of perimeter seal 50 increases. Because the rate of moisture permeation through perimeter seal 50 is inversely proportional to the width of the perimeter seal, the required width of first desiccant material 70 decreases by half as perimeter seal 50 doubles in width. As shown in this embodiment, the total width of the required first desiccant material 70 and perimeter seal 50 at first decreases as the perimeter seal width increases. However, a minimum of about 7 mm is reached when perimeter seal 50 is about 3.5 mm. The total width then increases with increasing perimeter seal width, because the width decrease of first desiccant material 70 is no longer greater than the increase in the width of perimeter seal 50. As shown in this embodiment, there is a minimum total width for required first desiccant material 70 and perimeter seal 50 of about 7 mm. It will be understood that the minimum total width for a given OLED device, and thus the selected seal width, will depend on a number of factors, including the type of seal (e.g. glass, metal, epoxy), the selected desiccant material (e.g. CaO, molecular sieves), and the desired moisture level in contact with OLED device 20. Thus, this method can be used to help increase the relative display area by reducing the total width of seal plus desiccant material, and thus reduce the portion of the display that must be given over to sealing against ambient conditions.

For prior art encapsulation methods that use only a single perimeter seal and a single perimeter desiccant, the relationship shown in FIG. 6 for the first desiccant material and the perimeter seal of the present invention can also be used to describe the relationship of the single perimeter seal and a single perimeter desiccant. For this prior art encapsulation method the figure demonstrates that efforts to decrease the rate of moisture permeation beyond the rate obtained at the minimum total perimeter and perimeter desiccant will require a wider total width than obtained at the minimum. As shown in this figure efforts to decrease the moisture permeation rate by a factor of 10 by increasing the perimeter seal from 3.5 mm to 35 mm would require increasing the total width of the single desiccant and single perimeter seal by a factor of about 5 from about 7 mm to about 35 mm.

It is an advantage of the current invention that the rate of moisture permeation into OLED devices can be significantly reduced without the requirement of the prior art to significantly increase the total width of the desiccant sealing arrangement. It is another advantage of the current invention that the rate of moisture permeation into OLED devices can be significantly reduced at the same total width of the desiccant sealing arrangement of the prior art. The following table shows the rate of water permeation calculated for two sealed devices in accordance with this invention and four comparative single-sealed devices. The inventive devices include a perimeter seal (75 micron seal thickness), an interior seal (75 micron seal thickness), and first and second desiccants (75 micron desiccant thickness) placed adjacent to and inside of the perimeter and interior seals, respectively. In these examples, the first and second desiccants are the same: calcium oxide in the first case, and molecular sieves in the second. The comparative devices have a single seal and a single desiccant with the same thickness as the inventive devices. The water permeation rates for the calcium oxide based devices are based on 256 mm² devices, and the water permeation rates for the molecular sieves based devices are based on 25 mm² devices.

| | | | | Mol. | Mol. | Mol. |
|---|---|---|---|---|---|---|
| | CaO | CaO | CaO | sieves | sieves | sieves |
| | single | single | double | single | single | double |
| | seal | seal | seal | seal | seal | seal |
| Type | Comp. | Comp. | Inventive | Comp. | Comp. | In- |
| | | | | | | ventive |
| Perimeter | 3.45 | 5.9 | 3.45 | 9 | 14 | 9 |
| seal width | | | | | | |
| (mm) | | | | | | |
| 1st desiccant | 3.45 | 2.0 | 3.45 | 9 | 5.75 | 9 |
| width (mm) | | | | | | |
| Interior seal | — | — | 1 | — | — | 1 |
| width (mm) | | | | | | |
| 2nd | — | — | 0.001 | — | — | 0.75 |
| desiccant | | | | | | |
| width (mm) | | | | | | |
| Total width | 6.9 | 7.9 | 7.9 | 18 | 19.75 | 19.75 |
| (mm) | | | | | | |
| H2O | 504 | 258 | 0.1 | 194 | 90 | 3.4 |
| permeation | | | | | | |
| rate (μg/yr) | | | | | | |

This table shows the comparison between a single seal/single desiccant as known in the prior art, and the double seal/double desiccant as described herein. The comparisons include a very aggressive desiccant (calcium oxide) and a less aggressive desiccant (molecular sieves). This table shows that this invention can reduce the moisture permeation rate to the OLED device by a factor from 26 to 2600 at the same total width of the desiccant sealing arrangement, or this invention can reduce the moisture permeation rate to the OLED device by a factor from 60 to 5000 at an increase of about 1 to 2 mm to the total width of the desiccant sealing arrangement. To achieve the same decrease in the moisture permeation rate by the prior art method would require an increase in the perimeter seal width by a factor of tens to thousands. A combination not shown in the table of a less aggressive first desiccant material (molecular sieves) and a very aggressive second desiccant material (calcium oxide) results in similar performance as shown. With this combination, the water permeation rate for a 25 mm² device would be 2.7 μg/yr, the second desiccant width would be only 0.08 mm, and the total width would be only 19.08 mm.

OLED devices that can be used in this invention have been well described in the art, and OLED device 20 can include layers commonly used for such devices. A bottom electrode is formed over OLED substrate 10 and is most commonly configured as an anode, although the practice of this invention is not limited to this configuration. Example conductors for this application include, but are not limited to, gold, iridium, molybdenum, palladium, platinum, aluminum or silver. Desired anode materials can be deposited by any suitable means such as evaporation, sputtering, chemical vapor deposition, or electrochemical means. Anode materials can be patterned using well known photolithographic processes.

Although not always necessary, it is often useful that a hole-transporting layer be formed and disposed over the anode. Desired hole-transporting materials can be deposited by any suitable way such as evaporation, sputtering, chemical vapor deposition, electrochemical processes, thermal transfer, or laser thermal transfer from a donor material. Hole-transporting materials useful in hole-transporting layers are well known to include compounds such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. in U.S. Pat. No. 3,180,730. Other suitable triarylamines substituted with one or more vinyl radicals and having at least one active hydrogen-containing group are disclosed by Brantley et al. in U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. Such compounds include those represented by structural Formula A. 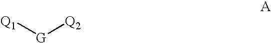
wherein:
Q₁ and Q₂ are independently selected aromatic tertiary amine moieties; and
G is a linking group such as an arylene, cycloalkylene, or alkylene group of a carbon to carbon bond.

In one embodiment, at least one of Q1 or Q2 contains a polycyclic fused ring structure, e.g., a naphthalene. When G is an aryl group, it is conveniently a phenylene, biphenylene, or naphthalene moiety.

A useful class of triarylamines satisfying structural Formula A and containing two triarylamine moieties is represented by structural Formula B. 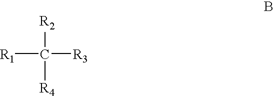
where:
R₁ and R₂ each independently represent a hydrogen atom, an aryl group, or an alkyl group or R₁ and R₂ together represent the atoms completing a cycloalkyl group; and
R₃ and R₄ each independently represent an aryl group, which is in turn substituted with a diaryl substituted amino group, as indicated by structural Formula C. 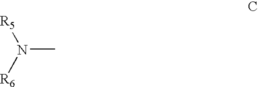
   wherein R₅ and R₆ are independently selected aryl groups. In one embodiment, at least one of R₅ or R₆ contains a polycyclic fused ring structure, e.g., a naphthalene.

Another class of aromatic tertiary amines are the tetraaryldiamines. Desirable tetraaryldiamines include two diarylamino groups, such as indicated by Formula C, linked through an arylene group. Useful tetraaryldiamines include those represented by Formula D. 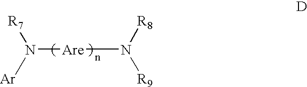
wherein:
each Are is an independently selected arylene group, such as a phenylene or anthracene moiety;
n is an integer of from 1 to 4; and
Ar, R₇, R₈, and R₉ are independently selected aryl groups.

In a typical embodiment, at least one of Ar, R₇, R₈, and R₉ is a polycyclic fused ring structure, e.g., a naphthalene.

The various alkyl, alkylene, aryl, and arylene moieties of the foregoing structural Formulae A, B, C, D, can each in turn be substituted. Typical substituents include alkyl groups, alkoxy groups, aryl groups, aryloxy groups, and halogens such as fluoride, chloride, and bromide. The various alkyl and alkylene moieties typically contain from 1 to about 6 carbon atoms. The cycloalkyl moieties can contain from 3 to about 10 carbon atoms, but typically contain five, six, or seven carbon atoms—e.g., cyclopentyl, cyclohexyl, and cycloheptyl ring structures. The aryl and arylene moieties are usually phenyl and phenylene moieties.

The hole-transporting layer in an OLED device can be formed of a single or a mixture of aromatic tertiary amine compounds. Specifically, one can employ a triarylamine, such as a triarylamine satisfying the Formula B, in combination with a tetraaryldiamine, such as indicated by Formula D. When a triarylamine is employed in combination with a tetraaryldiamine, the latter is positioned as a layer interposed between the triarylamine and the electron-injecting and transporting layer.

Another class of useful hole-transporting materials includes polycyclic aromatic compounds as described in EP 1 009 041. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate), also called PEDOT/PSS.

Light-emitting layers produce light in response to hole-electron recombination. The light-emitting layers are commonly disposed over the hole-transporting layer. Desired organic light-emitting materials can be deposited by any suitable way such as evaporation, sputtering, chemical vapor deposition, electrochemical process, or radiation thermal transfer from a donor material. Useful organic light-emitting materials are well known. As more fully described in U.S. Pat. Nos. 4,769,292 and 5,935,721, the light-emitting layers of the OLED element include a luminescent or fluorescent material where electroluminescence is produced as a result of electron-hole pair recombination in this region. The light-emitting layers can have a single material, but more commonly include a host material doped with a guest compound or dopant where light emission comes primarily from the dopant. The dopant is selected to produce color light having a particular spectrum. The host materials in the light-emitting layers can be an electron-transporting material, as defined below, a hole-transporting material, as defined above, or another material that supports hole-electron recombination. The dopant is usually chosen from highly fluorescent dyes, but phosphorescent compounds, e.g., transition metal complexes as described in WO 98/55561, WO 00/18851, WO 00/57676, and WO 00/70655 are also useful. Dopants are typically coated as 0.01 to 10% by weight into the host material. Host and emitting molecules known to be of use include, but are not limited to, those disclosed in U.S. Pat. Nos. 4,768,292; 5,141,671; 5,150,006; 5,151,629; 5,294,870; 5,405,709; 5,484,922; 5,593,788; 5,645,948; 5,683,823; 5,755,999; 5,928,802; 5,935,720; 5,935,721; and 6,020,078.

Metal complexes of 8-hydroxyquinoline and similar derivatives (Formula E) constitute one class of useful host materials capable of supporting electroluminescence, and are particularly suitable for light emission of wavelengths longer than 500 nm, e.g., green, yellow, orange, and red. 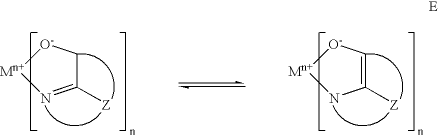
wherein:
M represents a metal;
n is an integer of from 1 to 3; and
Z independently in each occurrence represents the atoms completing a nucleus having at least two fused aromatic rings.

From the foregoing it is apparent that the metal can be a monovalent, divalent, or trivalent metal. The metal can, for example, be an alkali metal, such as lithium, sodium, or potassium; an alkaline earth metal, such as magnesium or calcium; or an earth metal, such as boron or aluminum. Generally any monovalent, divalent, or trivalent metal known to be a useful chelating metal can be employed.

Z completes a heterocyclic nucleus containing at least two fused aromatic rings, at least one of which is an azole or azine ring. Additional rings, including both aliphatic and aromatic rings, can be fused with the two required rings, if required. To avoid adding molecular bulk without improving on function the number of ring atoms is usually maintained at 18 or less.

The host material in the light-emitting layers can be an anthracene derivative having hydrocarbon or substituted hydrocarbon substituents at the 9 and 10 positions. For example, derivatives of 9,10-di-(2-naphthyl)anthracene constitute one class of useful host materials capable of supporting electroluminescence, and are particularly suitable for light emission of wavelengths longer than 400 nm, e.g., blue, green, yellow, orange or red.

Benzazole derivatives constitute another class of useful host materials capable of supporting electroluminescence, and are particularly suitable for light emission of wavelengths longer than 400 nm, e.g., blue, green, yellow, orange or red. An example of a useful benzazole is 2, 2′, 2″-(1,3,5-phenylene)tris[1-phenyl-1 H-benzimidazole].

Desirable fluorescent dopants include perylene or derivatives of perylene, derivatives of anthracene, tetracene, xanthene, rubrene, coumarin, rhodamine, quinacridone, dicyanomethylenepyran compounds, thiopyran compounds, polymethine compounds, pyrilium and thiapyrilium compounds, derivatives of distryrylbenzene or distyrylbiphenyl, bis(azinyl)methane boron complex compounds, and carbostyryl compounds.

Other organic emissive materials can be polymeric substances, e.g. polyphenylenevinylene derivatives, dialkoxy-polyphenylenevinylenes, poly-para-phenylene derivatives, and polyfluorene derivatives, as taught by Wolk et al. in commonly assigned U.S. Pat. No. 6,194,119 B1 and references cited therein.

Although not always necessary, it is often useful to include an electron-transporting layer disposed over the light-emitting layers. Desired electron-transporting materials can be deposited by any suitable way such as evaporation, sputtering, chemical vapor deposition, electrochemical processes, thermal transfer, or laser thermal transfer from a donor material. Preferred electron-transporting materials for use in the electron-transporting layer are metal chelated oxinoid compounds, including chelates of oxine itself (also commonly referred to as 8-quinolinol or 8-hydroxyquinoline). Such compounds help to inject and transport electrons and exhibit both high levels of performance and are readily fabricated in the form of thin films. Exemplary of contemplated oxinoid compounds are those satisfying structural Formula E, previously described.

Other electron-transporting materials include various butadiene derivatives as disclosed in U.S. Pat. No. 4,356,429 and various heterocyclic optical brighteners as described in U.S. Pat. No. 4,539,507. Certain benzazoles are also useful electron-transporting materials. Other electron-transporting materials can be polymeric substances, e.g. polyphenylenevinylene derivatives, poly-para-phenylene derivatives, polyfluorene derivatives, polythiophenes, polyacetylenes, and other conductive polymeric organic materials known in the art.

An upper electrode 75 most commonly configured as a cathode is formed over the electron-transporting layer, or over the light-emitting layers if an electron-transporting layer is not used. If the device is top-emitting, the electrode must be transparent or nearly transparent. For such applications, metals must be thin (preferably less than 25 nm) or one must use transparent conductive oxides (e.g. indium-tin oxide, indium-zinc oxide), or a combination of these materials. Optically transparent cathodes have been described in more detail in U.S. Pat. No. 5,776,623. Cathode materials can be deposited by evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

OLED device 20 can include other layers as well. For example, a hole-injecting layer can be formed over the anode, as described in U.S. Pat. Nos. 4,720,432, 6,208,075, EP 0 891 121 A1, and EP 1 029 909 A1. An electron-injecting layer, such as alkaline or alkaline earth metals, alkali halide salts, or alkaline or alkaline earth metal doped organic layers, can also be present between the cathode and the electron-transporting layer.

The invention has been described in detail with particular reference to certain preferred embodiments thereof, but it will be understood that variations and modifications can be effected within the spirit and scope of the invention.

### Parts List

10 substrate
20 OLED device
30 cover
40 desiccant sealing arrangement
50 perimeter seal
60 interior seal
70 first desiccant material
75 contact pad
80 second desiccant material
90 adhesive material
110 thin-film encapsulation layer
120 ledge
130 ledge
300 block
310 block
320 block
330 block
340 block
350 block
360 block
370 block
400 block
410 block
420 block
430 block
440 block
450 block
460 block
470 block

1. A method of encapsulating an OLED device, comprising:
(a) providing a substrate;
(b) forming an OLED device over the substrate, and a cover over the OLED device; and
(c) providing a desiccant sealing arrangement between the cover and the substrate, with the desiccant sealing arrangement provided by forming:
(i) a perimeter seal and a spaced interior seal;
(ii) a first desiccant material placed between the perimeter seal and the spaced interior seal; and
(iii) a second desiccant material placed interior of the spaced interior seal.

2. The method of claim 1 wherein the substrate defines two coplanar surfaces.

3. The method of claim 1 wherein the cover defines two coplanar surfaces.

4. The method of claim 3 wherein the substrate defines two coplanar surfaces.

5. The method of claim 1 wherein the first and second desiccant materials are particulate materials or particulate materials formed into a matrix.

6. The method of claim 1 wherein the second desiccant material has an equilibrium humidity level less than 1000 ppm.

7. The method of claim 6 wherein the first desiccant material has an equilibrium humidity level greater than 1000 ppm.

8. The method of claim 1 further providing one or more thin-film encapsulation layers over the OLED device.

9. The method of claim 1 wherein the cover is spaced from the OLED device and adhesive material is disposed between the OLED device and the cover.

10. The method of claim 1 wherein perimeter seal or the spaced interior seal or both include a glass ledge.

11. The method of claim 10 further providing that the distance between the first desiccant material and the substrate is less than the thickness of the perimeter seal to improve moisture absorption by the first desiccant material.

12. The method of claim 1 further including selecting the seal widths based on the type of seals, the desiccant materials, and the desired moisture level in contact with the OLED device.
